(19) United States
(12) Patent Application Publication
(10) Pub. No.: US 2022/0206388 A1
(43) Pub. Date: Jun. 30, 2022

(54) POSITIVE-TYPE PHOTOSENSITIVE RESIN COMPOSITION AND CURED FILM PREPARED THEREFROM

(71) Applicant: ROHM AND HAAS ELECTRONIC MATERIALS KOREA LTD., Chungcheongnam-do (KR)

(72) Inventors: Eun-Young LEE, Gyeonggi-do (KR); Ju-Young Jung, Gyeonggi-do (KR); Jin-Kyu Im, Gyeonggi-do (KR)

(21) Appl. No.: 17/543,568

(22) Filed: Dec. 6, 2021

(30) Foreign Application Priority Data
Dec. 28, 2020 (KR) 10-2020-0184357

(51) Int. Cl. G03F 7/075; C08F 220/32; C08F 220/14; C08F 220/18

(52) U.S. Cl. CPC G03F 7/0757; C08F 220/325; C08F 220/1811; C08F 220/1806; C08F 220/14

(57) ABSTRACT

The present invention relates to a positive-type photosensitive resin composition and a cured film prepared therefrom. The positive-type photosensitive resin composition, in which an acrylic copolymer and a siloxane copolymer are used together while a bulky monomer is introduced into the acrylic copolymer, facilitates the penetration of a developer and, at the same time, increases the inhibition efficiency of acid groups to produce the effect of improving the sensitivity.

### TECHNICAL FIELD

The present invention relates to a positive-type photosensitive resin composition and to a cured film prepared therefrom, More specifically, the present invention relates to a positive-type photosensitive resin composition, which provides excellent sensitivity, and to a cured film prepared therefrom to be used in a liquid crystal display, an organic EL display, and the like.

### BACKGROUND ART

In a display device such as a liquid crystal display device of a thin film transistor (TFT) type, an inorganic protective film made of; for example, silicon nitride has been used as a protective film for protecting and insulating the TFT circuit. However, since such an inorganic protective film has a problem in that it is difficult to enhance the aperture ratio due to its high dielectric constant, the demand for an organic insulation film having a low dielectric constant has been increasing.

A photosensitive resin, which is a polymeric compound that is chemically reacted with light or an electron beam to change its solubility to a specific solvent, is generally used for such an insulation film. The photosensitive resin is classified into a positive type and a negative type depending on the solubility of exposed portions to a developer. In the positive type, an exposed portion is dissolved by a developer to form a pattern. In the negative type, an exposed portion is not dissolved by a developer while the unexposed portion is dissolved to form a pattern.

Since a positive-type organic insulation film has no photo-curing component as compared with a negative-type organic insulation film, it is disadvantageous in that it is difficult to secure sensitivity and adhesion to an underlying film,

Thus, a photosensitive resin composition and a cured film prepared therefrom have been proposed in which a polysiloxane resin and an acrylic resin are employed together, thereby having excellent sensitivity and adhesiveness (see Japanese Patent No. 5099140). However, the sensitivity has not yet been improved to a satisfactory level,

### Prior Art Document

(Patent Document 1) Japanese Patent No. 5099140

### DISCLOSURE OF INVENTION

### Technical Problem

Accordingly, an object of the present invention is to provide a positive-type photosensitive resin composition in which an acrylic copolymer and a siloxane copolymer are used together While a bulky monomer is introduced into the acrylic copolymer, thereby facilitating the penetration of a developer and, at the same time, increasing the inhibition efficiency of acid groups to produce the effect of improving the sensitivity.

In addition, an object of the present invention is to provide a cured film prepared from the positive-type photosensitive resin composition to be used in a liquid crystal display, an organic EL display, and the like.

### Solution to Problem

In order to accomplish the above object, the present invention provides a positive-type photosensitive resin composition, which comprises (A) an acrylic copolymer; (B) a siloxane copolymer; and (C) a 1,2-quinonediazide compound, wherein the acrylic copolymer comprises a structural unit (a-1) represented by the following Formula 1 and a structural unit (a-2) represented by the following Formula 2 at a weight ratio of 1:4 to 4:1:

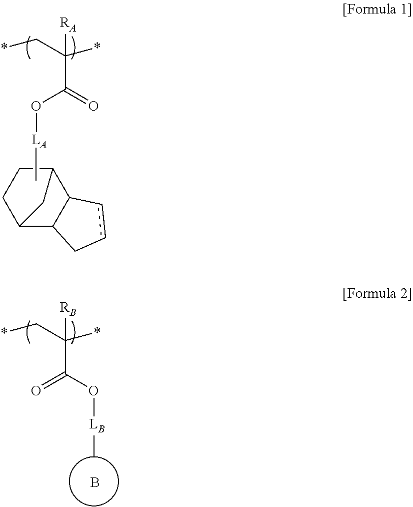

In the above formulae, R_{A} and R_{B} are each independently hydrogen or a methyl group; L_{A} and L_{B} are each independently a single bond or a chain having 1 to 6 carbon atoms with or without one or more heteroatoms; [symbol] is a single bond or a double bond; and Ring B is a monocyclic ring having 5 to 12 carbon atoms with or without heteroatoms wherein the ring B has, or does not have, a substituent comprising a, hydrocarbon having 1 to 12 carbon atoms, and the heteroatoms are each selected from the group consisting of N, O, and S.

In addition, the present invention provides a cured film formed from the positive-type photosensitive resin composition.

### Advantageous Effects of Invention

The positive-type photosensitive resin composition, in which an acrylic copolymer and a siloxane copolymer are used together while a bulky monomer is introduced into the acrylic copolymer, facilitates the penetration of a developer and, at the same time, increases the inhibition efficiency of acid groups to produce the effect of improving the sensitivity.

Accordingly, the positive-type photosensitive resin composition can be used for preparing a cured film to be used in a liquid crystal display, an organic EL display, and the like.

### BRIEF DESCRIPTION OF DRAWINGS

FIG. 1 is an electron microscope image of a cured film having a good surface roughness (surface roughness 1) in Test Example 4.

FIG. 2 is an electron microscope image of a cured film having a poor surface roughness (surface roughness 5) in Test Example 4.

### BEST MODE FOR CARRYING OUT THE INVENTION

The present invention is not limited to those described below. Rather, it can be modified into various forms as long as the gist of the invention is not altered.

Throughout the present specification, when a part is referred to as “comprising” an element, it is understood that other elements may be comprised, rather than other elements are excluded, unless specifically stated otherwise. in addition, all numbers and expressions relating to quantities of components, reaction conditions, and the like used herein are to be understood as being modified by the term “about” unless specifically stated otherwise.

As used herein, the term “(meth)acryl” refers to “acryl” and/or “methacryl,” and the term “(meth)acrylate” refers to “acrylate” and/or “methacrylate,”

In the present specification, the weight average molecular weight may refer to a weight average molecular weight measured by gel permeation chromatography (GPC, eluent: tetrahydrofuran) and referenced to a polystyrene standard. Typically, it does not accompany a unit, but it may be understood to have a unit of g/mole or Da.

### Positive-Type Photosensitive Resin Composition

The present invention relates to a positive-type photosensitive resin composition, in which the photosensitive-type resin composition comprises (A) an acrylic copolymer, (B) a siloxane copolymer, and (C) a 1,2-quinonediazide compound.

As an example, the positive-type photosensitive resin composition may comprise 10% by weight to 90% by weight of the acrylic copolymer, 5% by weight to 50% by weight of the siloxane copolymer, and 1% by weight to 20% by weight of the 1,2-quinonediazide compound based on the solids content exclusive of solvents.

In addition, the photosensitive resin composition may optionally further comprise (D) a multifunctional monomer, (E) a solvent, (F) an epoxy compound, (G) a surfactant, and/or (I) a silane compound.

Hereinafter, each component of the photosensitive resin composition will be explained in detail.

(A) Acrylic Copolymer

The photosensitive resin composition according to the present invention comprises an acrylic copolymer.

The acrylic copolymer is an alkali-soluble resin for achieving developability in the development step and also plays the role of a base for forming a film upon coating and a structure for forming a final pattern.

The acrylic copolymer comprises a structural unit (a-1) represented by the following Formula 1 and a structural unit (a-2) represented by the following Formula 2 at a weight ratio of 1:4 to 4:1.

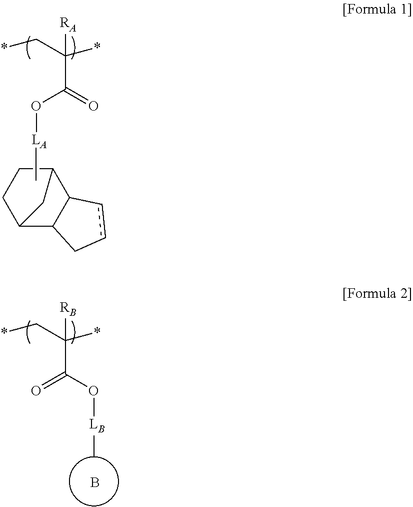

In the above formulae, R_{A} and R_{B} are each independently hydrogen or a methyl group; L_{A} and L_{B} are each independently a single bond or a chain having 1 to 6 carbon atoms with or without one or more heteroatoms; [symbol] is a single bond or a double bond; and Ring B is a monocyclic ring having 5 to 12 carbon atoms with or without heteroatoms, wherein the ring B has, or does not have, a substituent comprising a hydrocarbon having 1 to 12 carbon atoms, and the heteroatoms are each selected from the group consisting of N, O, and S.

As the acrylic copolymer (A) comprises the structural unit (a-1) and the structural unit (a-2) together, it is advantageous for improving the sensitivity while maintaining the film retention rate.

In addition, as the acrylic copolymer comprises the structural unit (a-1) and the structural unit (a-2) at a weight ratio of 1:4 to 4:1, the surface state of a cured film formed from the composition can be enhanced. For example, the weight ratio (a-1:a-2) between the structural units may be 1:4 to 4:1, 1:4 to 1:1, 1:1 to 4:1, 1:3 to 1:1, 1:1 to 3:1, 1:2 to 4:1, 1:4 to 2:1, 1:4 to 3:2, or 2:3 to 4:1.

The structural unit (a-1) has a hydrogen or a methyl group as the group R_{A} as shown in Formula 1. In addition, L_{A} may specifically be a single bond or may be alkylene or oxyalkylene having 1 to 6 carbon atoms or 1 to 3 carbon atoms.

As a specific example, the structural unit (a-1) may be derived from at least one compound selected from the group consisting of dicyclopentanyl acrylate, dicyclopentanyl methacrylate, dicyclopentenyl acrylate, dicyclopentenyl methacrylate, dicyclopentanyloxyethyl acrylate, dicyclopentanyloxyethyl methacrylate, dicyclopentenyloxyethyl acrylate, and dicyclopentenyloxyethyl methacrylate.

The content of the structural unit (a-1) may be 5 to 80% by weight, specifically, 10% by weight to 70% by weight, more specifically, 20% by weight to 60% by weight, based on the total weight of the acrylic copolymer (A). Within the above range, it is advantageous for securing excellent film retention rate, coating film characteristics, and sensitivity.

As shown in Formula 2, the structural unit (a-2) has a monocyclic moiety having 5 to 12 carbon atoms with or without a heteroatom as the ring B, wherein the ring B has, or does not have, a substituent comprising a hydrocarbon having 1 to 12 carbon atoms

As an example, the ring B may be a monocyclic alicyclic hydrocarbon group having 5 to 12 carbon atoms, specifically, a cycloalkyl having 5 to 10 carbon atoms such as cyclohexyl. Alternatively, it may be a group in which 1 to 3 heteroatoms selected from the group consisting of N, O, and S are inserted in the alicyclic hydrocarbon group. Specifically, the number of carbon atoms constituting the ring B may be 5 to 12, 5 to 10, or 5 to 8.

In addition, the ring B may have one or more substituents, wherein the substituent may specifically be an aliphatic hydrocarbon group having 1 to 12 carbon atoms, more specifically, an alkyl having 1 to 12 carbon atoms such as methyl. Alternatively, it may be a group in which 1 to 3 heteroatoms are inserted in the aliphatic hydrocarbon group. Specifically, the number of carbon atoms constituting the substituent in the ring B may be 1 to 12, 1 to 6, or 1 to 3.

In addition, L_{B} may be a single bond or may be alkylene or oxyalkylene having 1 to 6 carbon atoms or 1 to 3 carbon atoms.

As a specific example, the structural unit (a-2) may be derived from one or more compounds selected from the group consisting of cyclohexyl acrylate, cyclohexyl methacrylate, cyclohexylmethyl acrylate, cyclohexylmethyl methacrylate, 4-methylcyclohexylmethyl acrylate, and 4-methylcyclohexylmethyl methacrylate.

The content of the structural unit (a-2) may be 5 to 80% by weight, specifically, 10% by weight to 70% by weight, more specifically, 20% by weight to 60% by weight, based on the total weight of the acrylic copolymer (A). Within the above range, it is advantageous for securing excellent film retention rate, coating film characteristics, and sensitivity.

The acrylic copolymer may further comprise a structural unit (a-3) derived from an ethylenically unsaturated carboxylic acid, an ethylenically unsaturated carboxylic anhydride, or a combination thereof.

The ethylenically unsaturated carboxylic acid, the ethylenically unsaturated carboxylic anhydride, or a combination thereof is a polymerizable unsaturated compound containing at least one carboxyl group in the molecule. It may be at least one selected from an unsaturated monocarboxylic acid such as (meth)acrylic acid, crotonic acid, alpha-chloroacrylic acid, and cinnamic acid; an unsaturated dicarboxylic acid and an anhydride thereof such as maleic acid, maleic anhydride, fumaric acid, itaconic acid, itaconic anhydride; citraconic acid; citraconic anhydride, and mesaconic acid; an unsaturated polycarboxylic acid having three or more valences and an anhydride thereof; and a mono[(meth)acryloyloxyalkyl] ester of a polycarboxylic acid of divalence or more such as mono[2-(meth)acryloyloxyethyl] succinate, mono[2-(meth)acryloyloxyethyl] phthalate, and the like. But it is not limited thereto. (Meth)acrylic acid among the above is preferable from the viewpoint of developability.

The content of the structural unit (a-3) may be 5 to 30% by weight based on the total weight of the acrylic copolymer (A). Within the above range, it is possible to attain a pattern of a coating film with good developability.

The acrylic copolymer (A) may further comprise a structural unit (a-4) derived from an ethylenically unsaturated compound different from the structural units (a-1), (a-2), and (a-3). The ethylenically unsaturated compound different from the structural units (a-1), (a-2), and (a-3) may be at least one selected from the group consisting of an ethylenically unsaturated compound having an aromatic ring such as phenyl (meth)acrylate, benzyl (meth)acrylate, 2-phenoxyethyl (meth)acrylate, phenoxy diethylene glycol (meth)acrylate p-nonylphenoxy polyethylene glycol (meth)acrylate, p-nonylphenoxy polypropylene glycol (meth)acrylate, tribromophenyl (meth)acrylate, styrene, methylstyrene, dimethylstyrene, trimethylstyrene, ethylstyrene, diethylstyrene, triethylstyrene, propylstyrene, butylstyrene, hexylstyrene, heptylstyrene, octylstyrene, fluorostyrene, chlorostyrene, bromostyrene, iodostyrene, methoxystyrene, ethoxystyrene, propoxystyrene, p-hydroxy-α-methylstyrene, acetylstyrene, vinyl toluene, divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate dimethylarninoethyl (meth)acylate. ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate glycerol (rneth)acrylate methyl α-hydroxymethyacrylate, ethyl α-hydroxymethylacrylate, propyl α-hydroxymethylacrylate, butyl α-hydroxymethylacrylate, 2-methoxyethyl (meth)acrylate, 3-methoxybuty (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate; an unsaturated monomer containing an epoxy group such as glycidyl (meth)acrylate, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzypacrylamide, N-(4-(2,3-epoxypropoxy)-3,5-dimethylphenylpropyl)acrylamide, 4 -hydroxybutyl (meth)acrylate glycidyl ether, allyl glycidyl ether, and 2-methylallyl glycidyl ether; an N-vinyl tertiary amine containing an N-vinyl group such as N-vinyl pyrrolidone, N-vinyl carbazole, and N-vinyl morpholine; an unsaturated ether such as vinyl methyl ether and vinyl ethyl ether; and an unsaturated imide such as N-phenylmaleimide, N-(4-chlorophenyl)maleimide, N-(4-hydroxyphenyl)maleimide, and N-cyclohexylmaleimide.

The structural unit derived from the above-exemplified compounds may be comprised in the copolymer alone or in combination of two or more.

If the copolymer preferably comprises a structural unit derived from an ethylenically unsaturated compound containing an epoxy group among the above, more preferably a structural unit derived from glycidyl (meth)acrylate or 3,4-epoxycyclohexy I (meth)acrylate, it may be more advantageous from the viewpoint of the copolymerizability and improvements in the strength of an insulation film.

The content of the structural unit (a-4) may be 5 to 70% by weight, preferably, 15 to 65% by weight, based on the total weight of the structural units constituting the acrylic copolymer (A), Within the above range, it is possible to increase the mechanical properties and the thermosetting factors of the acrylic copolymer (i.e., alkali-soluble resin), so that the mechanical film properties and the chemical resistance characteristics upon the formation of a coating film from the photosensitive resin composition can be remarkably enhanced.

The acrylic copolymer (A) may be prepared by compounding each of the compounds that provide the structural units (a-1), (a-2), (a-3), and (a-4), and adding thereto a molecular weight controlling agent, a polymerization initiator, a solvent, and the like, followed by charging nitrogen thereto and slowly stirring the mixture for polymerization.

The molecular weight controlling agent may be a mercaptan compound such as butyl mercaptan, octyl mercaptan, lauryl mercaptan, or the like, or an α-methylstyrene dimer, but it is not particularly limited thereto. The polymerization initiator may be an azo compound such as 2,2′-azobisisobutyronitrile, 2,2′-azobis(2,4-dimethylvaleronitrile), and 2,2′-azobis(4-methoxy-2,4-dimethylvaleronitrile), or benzoyl peroxide; lauryl peroxide; t-butyl peroxypivalate; 1,1-bis(t-butylperoxy)cyclohexane, or the like, but it is not limited thereto. The polymerization initiator may be used alone or in combination of two or more thereof. In addition, the solvent may be any solvent commonly used in the preparation of an acrylic copolymer. It may preferably be methyl 3-methoxypropionate or propylene glycol monomethyl ether acetate (PGMEA).

In particular, it is possible to reduce the residual content of unreacted monomers by keeping the reaction time longer while maintaining the reaction conditions to be milder during the polymerization reaction. The reaction conditions and the reaction time are not particularly limited. For example, the reaction temperature may be adjusted to a temperature lower than the conventional temperature, for example, from room temperature to 60° C. or from room temperature to 65° C. Then, the reaction time is to be maintained until a sufficient reaction is carried out.

It is possible to reduce the residual content of unreacted monomers in the acrylic copolymer to a very minute level when the acrylic copolymer is prepared by the above process. Here, the term unreacted monomers (or residual monomers) of the acrylic copolymer as used herein refers to the amount of the compounds (i.e., monomers) that aim to provide the structural units (a-1) to (a-4) of the acrylic copolymer (A), but do not participate in the reaction (i.e., do not form a chain of the copolymer). Specifically, the content of unreacted monomers of the acrylic copolymer (A) remaining in the photosensitive resin composition of the present invention may be 2 parts by weight or less, preferably, 1 part by weight or less, based on 100 parts by weight of the acrylic copolymer (on the basis of solids content). Here, the term solids content may refer to the components of the composition, exclusive of solvents.

The weight average molecular weight (Mw) of the acrylic copolymer may be 5,000 to 20,000, preferably, 8,000 to 13,000. Within the above range, the adhesiveness to a substrate is excellent, the physical and chemical properties are good, and the viscosity is appropriate.

In addition, the acrylic copolymer may be a mixture of one or more acrylic copolymers comprising the above structural units. As an example, the acrylic copolymer may comprise (A1) a first acrylic copolymer comprising the structural unit (a-1) and the structural unit (a-2); and (A2) a second acrylic copolymer comprising the structural unit (a-3) derived from an ethylenically unsaturated carboxylic acid, an ethylenically unsaturated carboxylic anhydride, or a combination thereof and the structural unit (a-4) derived from an ethylenically unsaturated compound different from the structural units (a-1), (a-2), and (a-3). The acrylic copolymer composed of two or more types as described above may be employed in the composition in an amount of 10% by weight or more, or 30%); by weight or more, based on the solids content of the photosensitive resin composition of the present invention, exclusive of solvents.

The content of the acrylic copolymer may be 10 to 90% by weight, preferably, 10 to 70% by weight, more preferably, 10 to 60% by weight, based on the solids content of the photosensitive resin composition of the present invention, exclusive of solvents. Within the above content range, the developability is appropriately controlled, which is advantageous in terms of film retention rate.

(B) Siloxane Copolymer

The photosensitive resin composition according to the present invention comprises a polysiloxane, specifically, a siloxane copolymer.

The siloxane copolymer includes a condensate of a silane compound and/or a hydrolysate thereof. In such an event, the silane compound or the hydrolysate thereof may be a monofunctional to tetrafunctional silane compound.

As a result, the siloxane copolymer may comprise a siloxane structural unit selected from the following Q, T, D), and M types:
Q type siloxane structural unit: a siloxane structural unit comprising a silicon atom and four adjacent oxygen atoms, which may be derived from, e.g., a tetrafunctional silane compound or a hydrolysate of a silane compound that has four hydrolyzable groups.
T type siloxane structural unit: a siloxane structural unit comprising a silicon atom and three adjacent oxygen atoms, which may be derived from, e.g., a trifunctional silane compound or a hydrolysate of a silane compound that has three hydrolyzable groups.
D type siloxane structural unit: a siloxane structural unit comprising a silicon atom and two adjacent oxygen atoms (i.e., a linear siloxane structural unit), which may be derived from, e.g., a difunctional silane compound or a hydrolysate of a silane compound that has two hydrolyzable groups.
M type siloxane structural unit: a siloxane structural unit comprising a silicon atom and one adjacent oxygen atom, which may be derived from, e.g., a monofunctional silane compound or a hydrolysate of a silane compound that has one hydrolyzable group.

For example, the siloxane copolymer may comprise a structural unit derived from two or more silane compounds represented by the following Formula 3. For example, the siloxane copolymer may be a condensate of two or more silane compounds represented by the following Formula 3 and/or hydrolysates thereof.

(R¹)ₙSi(OR²)₄₋ₙ [Formula 3]

In Formula 3, n is an integer of 0 to 3, R¹ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, and R² is each independently hydrogen, C₁₋₆ alkyl, C₂₋₆ acyl, or C₆₋₁₅ aryl, wherein the heteroalkyl, the heteroalkenyl, and the heteroaryl groups each independently have at least one heteroatom selected from the group consisting of N, O, and S.

Examples of the structural unit wherein R¹ has a heteroatom may include an ether, an ester, and a sulfide.

In Formula 3, the compound may be a tetrafunctional silane compound where n is 0, a trifunctional silane compound where n is 1, a difunctional silane compound where n is 2, or a monofunctional silane compound where n is 3.

Particular examples of the silane compound may include, e.g., as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane; as the trifunctional silane compound, methyltrichlorosilane, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d³-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2(p-hydroxyphenyl)ethyltrimethoxysilane, 4-hydroxy-5-(p-hydroxyphenylcarbonyloxy)pentyltrimethoxysilane, trifluoromethyltriethoxysilane, 3,3,3 -trifluoropropyltrimethoxysilane, 3-aminopropyltrimethoxysilane, 3-aminopropyltriethoxysilane, 3 -glycidoxypropyltrimethoxysilane, 3-glycidoxypropyltriethoxysilane, 2-(3,4-epoxycyclohexyl)ethytrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3 -mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-gycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compound, trimethylmethoxysilane, tributylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, and butyltrimethoxysilane preferred among the difunctional silane compounds are dimethyldimethoxysilane, diphenyldimethoxysilane, diphenyldiethoxysilane, diphenyldiphenoxysilane, dibutydimethoxysilane, and dimethyldiethoxysilane.

Two or more of these silane compounds may be used in combination to prepare the siloxane copolymer.

The conditions for obtaining a hydrolysate or a condensate of the silane compound of the above Formula 3 are not particularly limited. For example, the silane compound of Formula 3 is optionally diluted with a solvent such as ethanol, 2-propanol, acetone, butyl acetate, or the like, and water and an acid (e.g., hydrochloric acid, acetic acid, nitric acid, or the like) or a base (e.g., ammonia, triethylamine, cyclohexylamine, tetramethylammonium hydroxide, or the like) as a catalyst are added thereto, followed by stirring the mixture to obtain the desired hydrolysate or condensate thereof.

The weight average molecular weight of the condensate (i.e., siloxane copolymer) obtained by the hydrolytic polymerization of the silane compound of the above Formula 3 is preferably in a range of 500 to 50,000. Within the above range, it is more preferable in terms of the film formation characteristics, solubility, dissolution rate to a developer, and the like.

The type and amount of the solvent or the acid or base catalyst are not particularly limited. In addition, the hydrolytic polymerization reaction may be carried out at a low temperature of 20° C. or lower. Alternatively, the reaction may be expedited by heating or refluxing.

The required reaction time may be adjusted depending on the type and concentration of the silane structural units, reaction temperature, and the like. For example, it usually takes 15 minutes to 30 days for the reaction to be carried out until the molecular weight of the condensate thus obtained becomes approximately 500 to 50,000. But it is not limited thereto.

The siloxane copolymer may comprise a linear siloxane structural unit (i.e., D-type siloxane structural unit). This linear siloxane structural unit may be derived from a difunctional silane compound, for example, a compound represented by the above Formula 3 where n is 2. Particularly, the siloxane copolymer may comprise the structural unit derived from the silane compound of the above Formula 3 where a is 2 in an amount of 0.5 to 50% by mole, preferably, 1 to 30% by mole, based on an Si atomic mole number. Within the above content range, it is possible that a cured film may have flexible characteristics while maintaining a certain level of hardness, whereby the crack resistance to an external stress can be further enhanced.

Further, the siloxane copolymer may comprise a structural unit derived from a silane compound represented by the above Formula. 3 where n is 1 (i.e., T-type structural unit). Preferably, the siloxane copolymer may comprise the structural unit derived from the silane compound of the above Formula 3 where n is 1 in an amount ratio of 40 to 85% by mole, more preferably, 50 to 80% by mole, based on an Si atomic mole number. Within the above content range, it is more advantageous for forming a precise pattern profile.

In addition, in consideration of the hardness, sensitivity, and retention rate of a cured film, it is preferable that the siloxane copolymer comprises a structural unit derived from a silane compound having an aryl group. For example, the siloxane copolymer may comprise the structural unit derived from a silane compound having an aryl group in an amount of 30 to 70% by mole, preferably, 35 to 50% by mole, based on an Si atomic mole number. Within the above content range, the compatibility of the siloxane copolymer with a 1,2-naphthoquinonediazide compound is excellent, which may prevent an excessive decrease in sensitivity while attaining more favorable transparency of a cured film. The structural unit derived from the silane compound having an aryl group may be, for example, a structural unit derived from a silane compound of the above Formula 3 where R¹ is an aryl group, preferably, a silane compound of the above Formula 3 where n is 1 and R¹ is an aryl group, particularly, a silane compound of the above Formula 3 where n is 1 and R¹ is a phenyl group.

The siloxane copolymer may comprise a structural unit derived from a silane compound represented by the above Formula 3 where n is 0 (i.e., Q-type structural unit). Preferably, the siloxane copolymer may comprise the structural unit derived from the silane compound represented by the above Formula 3 where n is 0 in an amount of 10 to 40% by mole, preferably, 15 to 35% by mole, based on an Si atomic mole number. Within the above content range, the photosensitive resin composition may maintain its solubility to an aqueous alkaline solution at a proper level during the formation of a pattern, whereby it is advantageous for preventing any defects caused by a reduction in the solubility or a drastic increase m the solubility of the composition.

The term “% by mole based on an Si atomic molar number” as used herein refers to a percentage of the number of moles of Si atoms contained in a specific structural unit with respect to the total number of moles of Si atoms contained in all of the structural units constituting the siloxane polymer.

The molar amount of a siloxane unit in the siloxane copolymer may be measured by the combination of Si-NMR, ¹H-NMR ¹³C-NMR, IR, TOF-MS, elementary analysis, measurement of ash, and the like. For example, in order to measure the molar amount of a siloxane unit having a phenyl group, an Si-NMR analysis is performed on the entire siloxane copolymer, followed by an analysis of the phenyl-bound Si peak area and the phenyl-unbound Si peak area. The molar amount can then be computed from the peak area ratio between them.

The content of the siloxane copolyrner may be 5 to 90% by weight, preferably, 5 to 50% by weight, more preferably, 5 to 40% by weight, based on the solids content of the photosensitive resin composition of the present invention, exclusive of solvents. Within the above content range, the developability is appropriately controlled, which is advantageous in terms of film retention rate.

In addition, the siloxane copolymer, when pre-cured, may have a dissolution rate of 50 Å /sec or more, preferably, 500 Å/sec or more, more preferably, 1,500 Å or more, in an aqueous solution of 1.5% by weight of tetramethylammonium hydroxide (TMAH). Within the above range of dissolution rate, high developability to a developer may secure better sensitivity and resolution. Meanwhile, the upper limit of the dissolution rate is not particularly limited. But it may be, for example, 100,000 Å/sec or less, 50,000 Å/sec or less, or 10,000 Å/sec or less.

(C) 1,2-Quintonediazide Compound

The photosensitive resin composition according to the present invention comprises a 1,2-quinonediazide compound.

The 1,2-quinonediazide compound may be a compound used as a photosensitive agent in the photoresist field.

Examples of the 1,2-quinonediazide compound may include an ester of a phenolic compound and 1,2-benzoquinonediazide-4-sulfonic acid or 1,2-benzoquinonediazide-5-sulfonic acid; an ester of a phenolic compound and 1,2-naphthoquinonediazide-4-sulfonic acid or 1,2-naphthoquinonediazide-5-sulfonic acid; a sulfonamide of a phenolic compound in which the hydroxyl group is substituted with an amino group and 1,2-benzoquinonediazide-4-sulfonic acid or 1,2-benzoquinonediazide-5-sulfonic acid; a sulfonamide of a phenolic compound in which the hydroxyl group is substituted with an amino group and 1,2-naphthoquinonediazide-4-sulfonic acid or 1,2-naphthoquinonediazide-5-sulfonic acid. The above compounds may be used alone or in combination of two or more thereof.

Examples of the phenolic compound include 2,3,4-trihydroxybenzophenone, 2,4,6-trihydroxybenzopherione, 2, 2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-trip-hydroxyphenypethane, bis(2,3,4-trihydroxyphenyl)methane, 2,2-bis(2,3,4-trihydroxyphenyl)propane, 1,1,3-tris(2,5-dimethyl-4-hydroxyphyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,7′,-hexanol, 2,2,4-trimethyl-7,2′,4′-trihydroxyflavane, and the like.

More particular examples of the 1,2-quinonediazide compound include an ester of 2,3,4-trihydroxybenzophenone and 1,2-naphthoquinonediazide-4-sulfonic acid, an ester of 2,3,4-trihydroxybenzophenone and 1,2-naphthoquinonediazide-5-sulfonic acid, an ester of 4,4′-[1-[4-[1-[4-hydroxyphenyl]1-methylethyl]phenyl]ethylidene]bisphenol and 1,2-naphthoquinonediazide-4-sulfonic acid, an ester of 4,4′-[1-[4-[1-[4-hydroxyphenyl]-1-methylethyl]phenyl]ethylidene]bisphenol and ,2-naphthoquinonediazide-5-sulfonic acid, and the like.

These may be used alone or in combination of two or more. When these preferred compounds are used, the transparency of the photosensitive resin composition may be enhanced.

The content of the 1,2-quinonediazide compound may be 1 to 20% by weight, preferably, 1 to 15% by weight, more preferably, 2 to 10% by weight, based on the solids content of the photosensitive resin composition of the present invention, exclusive of solvents. Within the above content range, a pattern is more readily formed, and it is possible to suppress such defects as a rough surface of a coated film upon the formation thereof and such a pattern shape as scum appearing at the bottom portion of the pattern upon development.

(D) Multifunctional Monomer

The photosensitive resin composition according to the present invention may comprise a di- or higher-multifunctional monomer to enhance the chemical resistance.

The multifunctional monomer has two or more functional groups, and it also has one or more ethylenic double bonds, so that it can be polymerized by the action of a photopolymerization initiator.

Specifically, the multifunctional compound may be selected from the group consisting of ethylene glycol di(meth)acrylate, propylene glycol di(meth)acrylate, diethylene glycol di(meth)acrylate, triethylene glycol di(meth)acrylate, 1,6-hexanediol di(meth)acrylate, polyethylene glycol di(meth)acrylate, polypropylene glycol di(meth)acrylate, glycerin tri(meth)acrylate, trimethylolpropane tri(meth)acrylate, pentaerythritol tri(meth)acrylate, a monoester of pentaerythritol tri(meth)acrylate and succinic, acid, pentaerythritol tetra(meth)acrylate, dipentaerythritol penta(meth)acrylate, dipentaerythritol hexa(meth)acrylate, a monoester of dipentaerythritol penta(meth)acrylate and succinic acid, caprolactone modified dipentaerythritol hexa(meth)acrylate, pentaerythritol triacrylate-hexamethylene diisocyanate (a reaction product of pentaerythritol triacrylate and hexamethylene diisocyanate), tripentaerythritol hepta(meth)acrylate, tripentaerythritol octa(meth)acrylate, bisphenol A epoxyacrylate, and a mixture thereof, but is not limited thereto.

Examples of a commercially available multifunctional monomer may include (i) bifunctional (meth)acrylate such as Aronix M-210, M-240, and M-6200 manufactured by Toagosei Co., Ltd., KAYARAD HDDA, HX-220, and R-604 manufactured by Nippon Kayaku Co., Ltd., and V-260, V-312, and V-335 HP manufactured by Osaka Yuki Kayaku Kogyo Co., Ltd.; and (ii) tri and more functional (meth)acrylate such as Aronix M-309, M-400, M-403, M-405, M-450, M-7100, M-8030, M-8060, and TO-1382 manufactured by Toagosei Co., Ltd., KAYARAD TMPTA, DMA, DPHA-40H, DPCA-20, DPCA-30, DPCA-60, and DPCA-120 manufactured by Nippon Kayaku Co., Ltd., and V-295, V-300, V-360, V-GPT, V-3PA, V-400, and V-802. manufactured by Osaka Yuki Kayaku Kogyo Co., Ltd.

The content of the multifunctional monomer may be 0.001 to 30% by weight, preferably, 0.1 to 20% by weight, more preferably, 1 to 10% by weight, based on the solids content of the photosensitive resin composition of the present invention, exclusive of solvents. Within the above content range, it is advantageous for securing excellent sensitivity, and it is possible to suppress such defects as a rough surface of a coated film upon the formation thereof and such a pattern shape as scum appearing at the bottom portion of the pattern upon development.

(E) Solvent

The photosensitive resin composition according to the present invention may be prepared as a liquid composition in which the above components are mixed with a solvent. The solvent may be, for example, an organic solvent.

The solvent of the present invention is not particularly limited as long as it can dissolve the above-mentioned components and is chemically stable. For example, the solvent may be alcohols, ethers, glycol ethers, ethylene glycol alkyl ether acetates, diethylene glycols, propylene glycol monoalkyl ethers, propylene glycol alkyl ether acetates, propylene glycol alkyl ether propionates, aromatic hydrocarbons, ketones, esters, or the like.

Particular examples of the solvent include methanol, ethanol, tetrahydrofuran, dioxane, methyl cellosolve acetate, ethyl cellosolve acetate, ethyl acetoacetate, ethylene glycol monomethyl ether, ethylene glycol monoethyl ether, ethylene glycol dimethyl ether, ethylene glycol diethyl ether, propylene glycol dimethyl ether, propylene glycol diethyl ether, diethylene glycol monomethyl ether, diethylene glycol monoethyl ether, diethylene glycol dimethyl ether, diethylene glycol ethyl methyl ether, propylene glycol monomethyl ether, propylene glycol monoethyl ether, propylene glycol monopropyl ether, dipropylene glycol dimethyl ether, dipropylene glycol diethyl ether, propylene glycol methyl ether acetate, propylene glycol ethyl ether acetate, propylene glycol propyl ether acetate, dipropylene glycol methyl ether acetate, propylene glycol butyl ether acetate, toluene, xylene, methyl ethyl ketone, 4-hydroxy-4-methyl-2-pentanone, cyclopentanone, cycohexanone, 2-heptanone, γ-butyrolactone, ethyl 2-hydroxypropionate, ethyl 2-hydroxy-2-methylpropionate, ethyl ethoxyacetate, ethyl hydroxyacetate, methyl 2-hydroxy-3-methyl'butanoate, methyl 2-methoxypropionate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, N-methylpyrrolidone and the like.

Preferred among the above are ethylene glycol alkyl ether acetates, diethylene glycols, propylene glycol monoalkyl ethers, propylene glycol alkyl ether acetates, ketones, and the like. In particular, preferred are diethylene glycol dimethyl ether, diethylene glycol ethyl methyl ether, dipropylene glycol dimethyl ether, dipropylene glycol diethyl ether, propylene glycol monomethyl ether, propylene glycol monoethyl ether, propylene glycol methyl ether acetate, methyl 2-methoxypropionate, γ-butyrolactone, 4-hydroxy-4-methyl-2-pentanone, and the like.

The solvents exemplified above may be used alone or in combination of two or more thereof.

The amount of the solvent in the photosensitive resin composition according to the present invention is not particularly limited. For example, the solvent may be employed such that the solids content is 10 to 90% by weight, preferably, 10 to 80% by weight, more preferably 10 to 70% by weight, based on the total weight of the photosensitive resin composition. The term solids content may refer to the components of the composition, exclusive of solvents. If the amount of the solvent is within the above range, the coating of the composition can be readily carried out, and the flowability thereof can be maintained at a proper level.

(F) Epoxy Compound

The photosensitive resin composition according to the present invention may further comprise an epoxy compound so as to increase the internal density of the siloxane binder (i.e., siloxane copolymer), thereby enhancing the chemical resistance of a cured film to be prepared therefrom.

The epoxy compound may be a homo-oligomer or a hetero-oligomer of an unsaturated monomer containing at least one epoxy group.

Examples of the unsaturated monomer containing at least one epoxy group may include glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, o-vinylbenzyl glycidyl ether, m-vinylbenzyl glycidyl ether, p-vinylbenzyl glycidyl ether, and a mixture thereof.

The epoxy compound may be synthesized by any methods well known in the art.

An example of the commercially available epoxy compound may be GHP03 (glycidyl methacrylate homopolymer, Miwon Commercial Co., Ltd.).

The epoxy compound may further comprise an additional structural unit. As a specific example, it may further comprise a structural unit derived from styrene; styrene containing an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; styrene containing a halogen such as fluorostyrene, chlorostyrene, bromostyrene, and iodostyrene; styrene containing an alkoxy substituent such as methoxystyrene, ethoxystyrene, and propoxystyrene; acetylstyrene such as p-hydroxy-α-methylstyrene; an ethylenically unsaturated compound containing an aromatic ring such as divinylbenzene, vinylphenol, o-vinylbenzyl methyl ether, m-vinylbenzyl methyl ether, p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, phenyl (meth)acrylate, benzyl (meth)acrylate, 2-phenoxyethyl (meth)acrylate, phenoxydiethylene glycol (meth)acrylate p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate dicyclopentanyl (meth)acrylate, dicyclopentenyl (meth)acrylate, dicyclopentanyloxyethy (meth)acrylate, and dicyclopentenyloxyethyl (meth)acrylate; a tertiary amine containing an N-vinyl group such as N-vinyl pyrrolidone, N-vinyl carbazole, and N-vinyl morpholine; an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, N-cyclohexylmaleimide, and the like. The structural unit derived from the compounds exemplified above may constitute the epoxy compound either alone or in combination of two or more thereof.

It is more advantageous for polymerizability of the composition that the epoxy compound further comprises a structural unit derived from styrene-based compounds among these examples. On the other hand, it is preferable from the viewpoint of chemical resistance that the epoxy compound does not contain a carboxyl group. Thus, it is preferable that it does not contain a structural unit derived from a monomer having a carboxyl group.

The additional structural unit may be employed in an amount of 0 to 70% by mole, preferably, 10 to 60% by mole, relative to the total number of moles of the structural units constituting the epoxy compound. Within the above content range, it may be more advantageous in terms of the film strength.

The weight average molecular weight of the epoxy compound may preferably be 100 to 30,000, more preferably, 1,000 to 15,000. If the weight average molecular weight of the epoxy compound is at least 100, a cured film. may have more excellent hardness. Also, if the weight average molecular weight of the epoxy compound is 30,000 or less, a cured film may have a uniform thickness, which is suitable for planarizing any steps thereon.

The content of the epoxy compound may be 0.001 to 20% by weight, preferably, 0.001 to 10% by weight, more preferably, 0.001 to 5% by weight, based on the solids content of the photosensitive resin composition of the present invention, exclusive of solvents, Within the above content range, the chemical resistance and adhesiveness of a cured film prepared from the photosensitive resin composition may be more excellent.

(G) Surfactant

The photosensitive resin composition of the present invention may further comprise a surfactant to enhance its coatability, if desired.

The kind of the surfactant is not particularly limited, but examples thereof include fluorine-based surfactants, silicone-based surfactants, non-ionic surfactants, and the like.

Specific examples of the surfactant may include fluorine- and silicon-based surfactants such as FZ-2122 supplied by Dow Corning Toray Co., Ltd., BM-1000 and BM-1100 supplied by BM CHEMIE Co., Ltd., Megapack F-142 D, F-172, F-173, and F-183 supplied by Dai Nippon Ink Chemical Kogyo Co., Ltd., Florad FC-135, FC-170 C, FC-430, and FC-431 supplied by Sumitomo 3M Ltd., Sufron S-112, S-113, S-131, S-141 S-145 S-382, SC-101, SC-102, SC-103 SC-104, SC-105, and SC-106 supplied by Asahi Glass Co., Ltd., Eftop EF301, EF303, and EF352 supplied by Shinakida Kasei Co., Ltd., SH-28 PA, SH-190, SH-193, SZ-6032, SF-8428, DC-57, and. DC-190 supplied by Toray Silicon Co., Ltd.; non-ionic surfactants such as polyoxyethylene alkyl ethers including polyoxyethylene lauryl ether, polyoxyethylene stearyl ether, polyoxyethylene oleyl ether, and the like; polyoxyethylene aryl ethers including polyoxyethylene octylphenyl ether, polyoxyethylene nonylphenyl ether, and the like; and polyoxyethylene dialkyl esters including polyoxyethylene dilaurate, polyoxyethylene distearate, and the like; and organosiloxane polymer KP341 (manufactured by Shin-Etsu Chemical Co., Ltd.), (meth)acrylate-based copolymer Polyflow Nos. 57 and 95 (manufactured by Kyoei Yuji Chemical Co., Ltd.), and the like. They may be used alone or in combination of two or more thereof.

The content of the surfactant may be 0.001 to 5% by weight, preferably, 0.001 to 3% by weight, more preferably, 0.001 to 2% by weight, based on the solids content of the photosensitive resin composition of the present invention, exclusive of solvents. Within the above content range, the coating of the photosensitive resin composition may be more smoothly carried out.

(11) Silane Compound

The photosensitive resin composition of the present invention may comprise at least one silane compound represented by the following Formula 4, particularly, silane monomers of T type and/or Q type, to thereby enhance the chemical resistance during the treatment in the post-processing by reducing highly reactive silanol groups (Si-Off) in the siloxane copolymer, in association with the epoxy compound, for instance, epoxy oligomers.

(R³)ₘSi(OR⁴)₄₋ₘ [Formula 4]

In Formula 4, n is an integer of 0 to 3, R³ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, and R⁴ is each independently hydrogen, C₁₋₆ alkyl, C₂₋₆ acyl, or C₆₋₁₅ aryl, wherein the heteroalkyl, the heteroalkenyl, and the heteroaryl groups each independently have at least one heteroatom selected from the group consisting of N, O, and S.

Examples of the structural unit wherein R³ has a heteroatom include an ether, an ester, and a sulfide.

According to the present invention, it may be a tetrafunctional silane compound where m is 0, a trifunctional silane compound where m is 1, a difunctional silane compound where m is 2, or a monofunctional silane compound where m is 3.

Particular examples of the silane compound may include, e.g., as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane as the trifunctional silane compound, methyltrimethoxysilane, methytriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, phenyltrimethoxysilane, phenyltriethoxysilane, d³-methyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrmethoxysilane, 1-(p-hydroxyphenyl)ethyltrimethoxysilane, 2-(p-hydroxyphenyl)ethyltrimethoxysilane, 4- hydroxy-5 -(p-hydroxyphenylcarbonyloxy)pentyltrimethoxysilane, 3-aminopropyltrimethoxysilane, 3-aminopropyltriethoxysilane, 3-glycidoxypropyltrimethoxysilane, 3glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-mercaptopropyldimethoxymethysilane cyclohexyldimethoxymethylsilane, diethoxymethylvinylsilane dimethoxymethylvinylsilane, and dimethoxydi-p-tolyisilane; and as the monofunctional silane compound, trimethylmethoxysilane, tributylethoxysila.ne (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane, preferred among the trifunctional silane compounds are methyttrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, butyltrimethoxysilane, 3-glycidoxypropyltrimethoxysilane, 3-glycidoxypropyltriethoxysilane, 2-(3,4-epoxycyclohexyl)ethyltrimethoxysilane, and 2-(3,4-epoxycyclohexyl)ethyltriethoxysilane; and preferred among the difunctional silane compounds are dimethyldimethoxysilane, diphenyl dimethoxysilane, diphenyldiethoxysilane, diphenyldiphenoxysilane, dibutyldimethoxysilane, and dimethyldiethoxysilane.

These silane compounds may be used alone or in combination of two or more thereof.

The content of the silane compound may be 0.001 to 20% by weight, preferably, 0.001 to 10% by weight, more preferably, 0.001 to 5% by weight, based on the solids content of the photosensitive resin composition of the present invention, exclusive of solvents. Within the above content range, the coating of the photosensitive resin composition may be more smoothly carried out.

In addition, the photosensitive resin composition of the present invention may further comprise other additives as long as the physical properties of the photosensitive resin composition are not adversely affected.

Cured Film

The positive-type photosensitive resin composition according to the present invention, in which an acrylic copolymer and a siloxane copolymer are used together while a bulky monomer is introduced into the acrylic copolymer, facilitates the penetration of a developer and, at the same time, increases the inhibition efficiency of acid groups to produce the effect of improving the sensitivity. Specifically, the copolymer unit having a bulky residue provides free space to facilitate bonding of the acid groups with the photoactive agent, so that a high effect can be ac sieved even with a small amount of the photoactive agent in the process of decomposition by exposure to light.

Thus, the photosensitive resin composition may be used as a positive-type photosensitive resin composition for preparing a cured film.

Accordingly, the present invention provides a cured film formed from the photosensitive resin composition. The cured film may be formed by a method known in the art, for example, a method in which the photosensitive resin composition is coated on a substrate and then cured. More specifically, in the curing step, the photosensitive resin composition coated on a substrate may be subjected to pre-bake at a temperature of, for example, 60° C. to 130° C. to remove solvents; then exposed to light using a photomask having a desired pattern; and subjected to development using a developer, for example, a tetramethylammonium hydroxide (TMAH) solution, to form a pattern on the coating layer. Thereafter, the patterned coating layer, if necessary, is subjected to post-bake, for example, at a temperature of 150 to 300° C. for 10 minutes to 5 hours to prepare a desired cured film. The exposure to light may be carried out at an exposure dose of 10 mJ/cm² to 200 mJ/cm² based on a wavelength of 365 nm in a wavelength band of 200 nm to 500 nm. According to the process of the present invention, it is possible to easily form a desired pattern from the viewpoint of the process.

The coating of the photosensitive resin composition onto a substrate may be carried out by a spin coating method, a slit coating method, a roll coating method, a screen printing method, an applicator method, or the like, in a desired thickness of, e.g., 2 to 25 μm. In addition, as a light source used for the exposure (irradiation), a low-pressure mercury lamp, a high-pressure mercury lamp, an extra high-pressure mercury lamp, a metal halide lamp, an argon gas laser, or the like may be used. X-rays, electronic rays, or the like may also be used, if desired. The photosensitive resin composition of the present invention is capable of forming a cured film that is excellent in terms of the thermal resistance, transparency, dielectric constant, solvent resistance, acid resistance, and alkali resistance. Therefore, the cured film of the present invention thus formed. has excellent light transmittance devoid of surface roughness when it is subjected to thermal treatment or is immersed in, or comes into contact with a solvent, an acid, a base, or the like. Thus, the cured film can be effectively used as a planarization film for a thin-film transistor (TFT) substrate of a liquid crystal display or an organic EL display; barrier ribs for an organic EL display; an interlayer dielectric of a semiconductor device; a core or cladding material of an optical waveguide, or the like. Further, the present invention provides an electronic component that comprises the cured film as a protective film (or an insulation film).

### Mode for the Invention

Hereinafter, the present invention will be described in more detail with reference to the following examples. However, these examples are provided to illustrate the present invention, and the scope of the present invention is not limited thereto only.

In the following preparation examples, the weight average molecular weight is determined by gel permeation chromatography (GPC, eluent: tetrahydrofuran) referenced to a polystyrene standard.

### Preparation Example 1: Acrylic Copolymers (A-1 to A-6)

A flask equipped with a cooling tube and a stirrer was charged with 200 parts by weight of propylene glycol monomethyl ether acetate (PGMEA) as a solvent, and the temperature of the solvent was raised to 60° C. while the solvent was slowly stirred. Next, added thereto were 9.91 parts by weight of styrene, 4.51 parts by weight of glycidyl methacrylate, 16.38 parts by weight of methacrylic acid, and 69.21 parts by weight of dicyclopentanyl methacrylate, followed by dropwise addition of 3 parts by weight of 2,2′-azobis(2,4-dimethylvaleronitrile) as a radical polymerization initiator over 5 hours to carry out the polymerization reaction for 3 hours while maintaining the temperature. As a result, an acrylic copolymer (A-1) having a solids content of 23.50% by weight and a weight average molecular weight of about 9,000 to 11,000 was obtained. In addition, acrylic copolymers (A-2 to A-6) were prepared in the same manner according to the monomer composition shown in Table 1 below.

### Preparation Example 2: Acrylic copolymers (A-7 to A10)

A flask equipped with a cooling tube and a stirrer was charged with 200 parts by weight of PGMEA as a solvent, and the temperature of the solvent was raised to 10° C. while the solvent was slowly stirred. Next, added thereto were 19.76 parts by weight of styrene, 28.50 parts by weight of methyl methacrylate, 26.97 parts by weight of glycidyl methacrylate, 11.70 parts by weight of methacrylic acid, and 13.07 parts by weight of methyl acrylate, followed by dropwise addition of 3 parts by weight of 2,2′-azobis(2,4-dimethylvaleronitrile) as a radical polymerization initiator over 5 hours to carry out the polymerization reaction. As a result, an acrylic copolymer (A-7) having a solids content of 33.00% by weight and a weight average molecular weight of about 9,000 to 11,000 was obtained. In addition, acrylic copolymers (A-8 to A-10) were prepared in the same manner according to the monomer composition shown in Table 1 below.

### Preparation Example 3: Siloxane Copolymer (BA)

A reactor equipped with a reflux condenser was charged with 20 parts by weight of phenyltrimethoxysi lane, 30 parts by weight of methyltrimethoxysilane, 20 parts by weight of tetraethoxysilane, 15 parts by weight of deionized water, and 15 parts by weight of :PGME. Thereafter, the mixture was stirred under reflux in the presence of 50 ppm of a phosphoric acid catalyst for 6 hours, cooled, and then diluted with PGMEA. As a result, a siloxane copolymer having a solids content of 30% by weight and a weight average molecular weight of about 6,000 to 11,000 was obtained.

The alkali dissolution rate (ADR) of the siloxane copolymer was measured and shown in Table 2 below. Specifically, the siloxane copolymer was diluted with PGMEA to a concentration of 17% by weight of the solids content and cured at 105° C. for 90 seconds to form a coating film with a thickness of 10,000 Å. Then, the dissolution rate per second was measured using an aqueous solution of 1.5% by weight of tetramethylammonium hydroxide (TMAH).

### Preparation Example 4: Epoxy Compound (FA)

A three-necked flask was equipped with a cooling tube and placed on a stirrer equipped with a thermostat. The flask was charged with 100 parts by weight of 3,4-epoxycyclohexylmethyl methacrylate as a monomer, 10 parts by weight of 2,2′-azobis(2-methylbutyronitrile) as an initiator, and 100 parts by weight of PGMEA as a solvent, followed by charging nitrogen thereto, Thereafter, the temperature of the solution was raised to 80° C. while the solution was slowly stirred, which was maintained for 5 hours and then diluted with PGMEA. As a result, an epoxy copolymer having a solids content of 20% by weight and a weight average molecular weight of about 3,000 to 6,000 was obtained.

The monomer content, solids content, and weight average molecular weight of the copolymers prepared in Preparation Examples 1 to 3 are shown in Tables 1 and 2. below.

TABLE 1

| | Acrylic copolymer (part by weight) | | | | | | | Solids | |
|---|---|---|---|---|---|---|---|---|---|
| | a-1 | a-2 | a-3 | a-4 | | | | content | |
| | DCPMA | CHMA | MA | Sty | MMA | MAA | GMA | (wt %) | Mw |
| A-1 | 69.21 | 0.00 | 0.00 | 9.91 | 0.00 | 16.38 | 4.51 | 23.50 | 9,000 to 11,000 |
| A-2 | 57.18 | 11.02 | 0.00 | 10.23 | 0.00 | 16.92 | 4.65 | 24.00 | 9,000 to 11,000 |
| A-3 | 44.34 | 22.78 | 0.00 | 10.58 | 0.00 | 17.49 | 4.81 | 24.00 | 9,000 to 11,000 |
| A-4 | 30.60 | 35.37 | 0.00 | 10.95 | 0.00 | 18.10 | 4.98 | 24.00 | 9,000 to 11,000 |
| A-5 | 15.85 | 48.88 | 0.00 | 11.35 | 0.00 | 18.76 | 5.16 | 28.20 | 9,000 to 11,000 |
| A-6 | 0.00 | 63.40 | 0.00 | 11.77 | 0.00 | 19.47 | 5.36 | 28.00 | 9,000 to 11,000 |
| A-7 | 0.00 | 0.00 | 11.70 | 19.76 | 28.50 | 13.07 | 26.97 | 33.00 | 9,000 to 11,000 |
| A-8 | 0.00 | 0.00 | 11.73 | 19.81 | 26.67 | 14.74 | 27.04 | 33.00 | 9,000 to 11,000 |
| A-9 | 0.00 | 0.00 | 11.99 | 20.25 | 31.14 | 15.90 | 20.72 | 32.44 | 9,000 to 11,000 |
| A-10 | 0.00 | 0.00 | 12.02 | 20.30 | 29.27 | 17.62 | 20.78 | 32.67 | 9,000 to 11,000 |

DCPMA: dicyclopentanyl methacrylate,
CHMA: cyclohexylmethyl methacrylate,
MA: methacrylic acid,
Sty: styrene,
MMA: methyl methacrylate,
MAA: methyl acrylate,
GMA: glycidyl methacrylate

TABLE 2

| | Siloxane copolymer (part by weight) | | | | | | Solids | |
|---|---|---|---|---|---|---|---|---|
| | | | | Deionized | | ADR | content | |
| | PhTMOS | MTMOS | TEOS | water | PGMEA | (1.5% TMAH) | (wt %) | Mw |
| B-1 | 20 | 30 | 20 | 15 | 15 | 4113 Å/sec | 30 | 6,000 to |
| | | | | | | | | 11,000 |

PhTMOS: phenyltrimethoxysilane,
MTMOS: methyltrimethoxysilane,
TEOS: tetraethoxysilane,
PGMEA: propylene glycol monomethyl ether acetate,
TMAH: tetramethylammonium hydroxide

TABLE 3

| | | Chemical composition or | Solids content | |
|---|---|---|---|---|
| | Component | brand name | (wt %) | Manufacturer |
| A-1 to A-6 | Acrylic copolymer | Composition of Table 1 | 24-28 | SMS |
| A-7 to A-10 | | | 32-34 | Miwon |
| B-1 | Siloxane copolymer | Composition of Table 2 | 30 | Kyung-in |
| | | | | Synthetic Corp. |
| C-1 | 1,2-quinonediazide | THA-523 | 100 | Miwon |
| C-2 | compound | TPA-523 | 100 | Miwon |
| D-1 | Multifunctional | Dipentaerythritol | 100 | Nippon Gayaku |
| | monomer | hexaacrylate (DPHA) | | |
| E-1 | Solvent | Propylene glycol | — | Chemtronics |
| | | monomethyl ether acetate | | |
| F-1 | Epoxy compound | 3,4-epoxycycloheylmethyl | 20 | Miwon |
| | | methacrylate homopolymer, | | |
| | | GHP24P | | |
| G-1 | Surfactant | Silicone-based compound, | 100 | Dow Corning |
| | | FZ-2122 | | Tory |
| H-1 | Silane compound | OFS-6124 | 100 | Xiameter |

### Example 1: Preparation of a Photosensitive Resin Composition

15.46 parts by weight of A-4, 12.37 parts by weight of A-9, and 41.24 parts by weight of A-10 obtained in Preparation Examples 1 and 2 as an acrylic copolymer, 30.93 parts by weight of B-1 obtained in Preparation Example 3 as a siloxane copolymer, 7.29 parts by weight of C-1 and 9.94 parts by weight of C-2 as a 1,2-quinonediazide compound, 5.30 parts by weight of D-1 as a multifunctional monomer, 3.09 parts by weight of F-1 as an epoxy compound, 0.32 part by weight of G-1 as a surfactant, and 6.63 parts by weight of H-1 as a silane compound were mixed, followed by addition of E-1 as a solvent for dilution thereof and stirring of the mixture for 3 hours. It was filtered through a membrane filter having a pore size of 0.2 μm to obtain a composition having a solids content of 20% by weight.

### Examples 2 and 3 and Comparative Examples 1 to 3: Preparation of Photosensitive Resin Compositions

The components shown in Tables 4 to 6 below were mixed, diluted with a solvent, stirred, and filtered in the same manner as Example 1 to obtain a composition having a solids content of 20% by weight. Here, a mixture of E-1 and E-2 (7:3, w/w) was used as a solvent in Comparative Example 1, and E-1 was used as a solvent in Examples 2 and 3 and Comparative Examples 2 and 3.

The components and contents (solids content) of the compositions prepared in the Examples and Comparative Examples are shown in Tables 4 to 6.

TABLE 4

| | Acrylic copolymer | | | | | | Siloxane copolymer | |
|---|---|---|---|---|---|---|---|---|
| Ex. 1 | A-4 | 15.46 | A-9 | 12.37 | A-10 | 41.24 | B-1 | 30.93 |
| Ex. 2 | A-5 | 15.46 | A-9 | 12.37 | A-10 | 41.24 | B-1 | 30.93 |
| Ex. 3 | A-3 | 15.46 | A-9 | 16.49 | A-10 | 37.11 | B-1 | 30.93 |
| C. Ex. 1 | — | — | A-7 | 35.82 | A-8 | 33.25 | B-1 | 30.93 |
| C. Ex. 2 | A-1 | 15.46 | A-9 | 20.62 | A-10 | 32.99 | B-1 | 30.93 |
| C. Ex. 3 | A-2 | 15.46 | A-9 | 20.62 | A-10 | 32.99 | B-1 | 30.93 |

TABLE 5

| | | | | | Multifunctional | | Epoxy | |
|---|---|---|---|---|---|---|---|---|
| | 1,2-Quinonediazide compound | | | | monomer | | compound | |
| Ex. 1 | C-1 | 7.29 | C-2 | 9.94 | D-1 | 5.30 | F-1 | 3.09 |
| Ex. 2 | C-1 | 7.29 | C-2 | 9.94 | D-1 | 5.30 | F-1 | 3.09 |
| Ex. 3 | C-1 | 7.29 | C-2 | 9.94 | D-1 | 5.30 | F-1 | 3.09 |
| C. Ex. 1 | C-1 | 7.29 | C-2 | 9.94 | D-1 | 5.30 | F-1 | 3.09 |
| C. Ex. 2 | C-1 | 7.29 | C-2 | 9.94 | D-1 | 5.30 | F-1 | 3.09 |
| C. Ex. 3 | C-1 | 7.29 | C-2 | 9.94 | D-1 | 5.30 | F-1 | 3.09 |

TABLE 6

| | Surfactant | | Silane compound | |
|---|---|---|---|---|
| Ex. 1 | G-1 | 0.32 | H-1 | 6.63 |
| Ex. 2 | G-1 | 0.32 | H-1 | 6.63 |
| Ex. 3 | G-1 | 0.32 | H-1 | 6.63 |
| C. Ex. 1 | G-1 | 0.32 | H-1 | 6.63 |
| C. Ex. 2 | G-1 | 0.32 | H-1 | 6.63 |
| C. Ex. 3 | G-1 | 0.32 | H-1 | 6.63 |

Test Example 1: Evaluation of Sensitivity

The compositions prepared in the Examples and Comparative Examples were each coated onto a glass substrate by spin coating, which was then pre-baked on a hot plate kept at 105° C. for 105 seconds to form a dried film. A mask having a pattern of square holes m a size ranging from 1 μm to 30 μm was placed on the dried film. The film was then exposed to light using an aligner (model name: MA6) that emits light having a wavelength of 200 nm to 450 nm. The exposure was carried out for a certain period of time at a dose of 150 mJ/cm² based on 365 nm with the distance between the mask and the substrate set to 25 μm. It was then developed for 85 seconds with a developer, which was an aqueous solution of 2.38% by weight of tetramethylammonium hydroxide, through puddle nozzles at 23° C. The developed film was then exposed to light at a dose of 200 mJ/cm² based on a wavelength of 365 nm for a certain period of time using an aligner (model name: MA6) that emits light having a wavelength of 200 nm to 450 nm (i.e., bleaching step). It was then post-baked in a convection oven at 240° C. for 20 minutes to prepare a cured film having a thickness of 3.5 μm. In the above process, the exposure energy (mJ/cm²) was measured when the critical dimension (CD) of the pattern formed through the 11 μm-sized hole in the mask was achieved to be 10 μm. The lower the exposure energy, the more excellent the sensitivity.

### Test Example 2: Film Retention Rate

The compositions prepared in the Examples and Comparative Examples were each coated onto a glass substrate by spin coating, which was then pre-baked on a hot plate kept at 105° C. for 105 seconds to form a dried film. It was then developed for 80 seconds with a developer, which was an aqueous solution of 2.38% by weight of tetramethylammonium hydroxide, through puddle nozzles at 23° C. The developed film was then exposed to light at a dose of 200 mJ/cm² based on a wavelength of 365 nm for a certain period of time using an aligner (model name: MA6) that emits light having a wavelength of 200 nm to 450 nm (i.e., bleaching step). It was then post-baked in a convection oven at 240° C. for 20 minutes to prepare a cured film having a thickness of 2.1 μm. The film thickness after pre-bake and the film thickness after post-bake were measured using a film thickness measuring device (SNU Precision). The film retention rate (%) was calculated according to the following equation.

Film retention rate (%)=(thickness of film upon hard-bake/thickness of film upon pre-bake)×100

The larger the film retention rate, the more excellent. When it is 65% or more, it may be considered to be favorable.

### Test Example 3: Surface Roughness

The compositions prepared in the Examples and Comparative Examples were each coated onto a glass substrate by spin coating, which was then pre-baked on a hot plate kept at 105° C. for 105 seconds to form a dried film. A mask having a pattern of square holes m a size ranging from 1 μm to 30 μm was placed on the dried film. The film was then exposed to light using an aligner (model name: MA6) that emits light having a wavelength of 200 nm to 450 nm through an i-line optical filter. The exposure was carried out for a certain period of time at a dose of 150 MJ/cm² based on 365 nm with the distance between the mask and the substrate set to 25 μm, it was developed for 85 seconds with a developer, which was an aqueous solution of 2.38% by weight of tetramethylammonium hydroxide, through puddle nozzles at 23° C. The developed film was then exposed to light at a dose of 200 mJ/cm² based on a wavelength of 365 nm for a certain period of time using an aligner (model name: MA6) that emits light having a wavelength of 200 nm to 450 nm (i.e., bleaching step). It was then post-baked in a convection oven at 240° C. for 20 minutes to prepare a cured film having a thickness of 3.5 μm.

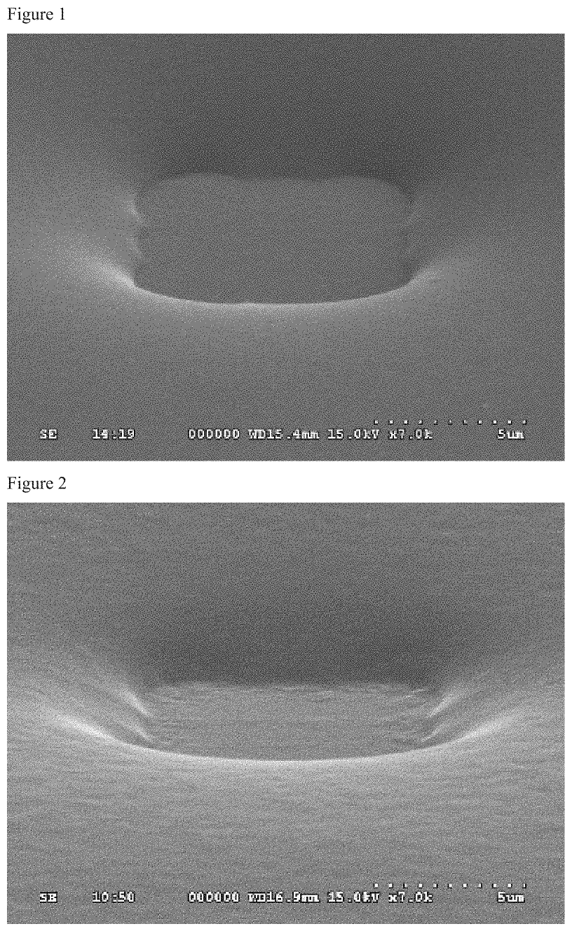

The surface of the film formed by the above procedure was observed by SEM, and the surface roughness was quantified as “1 to 5.” FIG. 1 is an electron microscope image of a film corresponding to surface roughness 1. FIG. 2 is an electron microscope image of a film corresponding to surface roughness 5. The smaller the surface roughness, the better. In Table 7 below, when the surface roughness was 1 to 2, it was indicated as ○ otherwise, it was indicated as x.

The results of the Test Examples are shown in the table below.

TABLE 7

| | Film | Sensitivity (mJ/cm²) | |
|---|---|---|---|
| | retention rate | roughness | Surface |
| Ex. 1 | 73.1 | 70.5 | ○ |
| Ex. 2 | 73.8 | 73.8 | ○ |
| Ex. 3 | 72.4 | 64.5 | ○ |
| C. Ex. 1 | 73.5 | 80.0 | × |
| C. Ex. 2 | 77.4 | 55.0 | × |
| C. Ex. 3 | 72.5 | 60.2 | × |

As shown in Table 7, the compositions of Examples 1 to 3 were excellent in sensitivity and surface roughness, while having a good film retention rate of 65% or more after post-bake. In contrast, the compositions of Comparative Examples 1 to 3 were poor in sensitivity evaluated during the curing process and also poor in surface roughness of the cured film.

1. A positive-type photosensitive resin composition, which comprises:
(A) an acrylic copolymer;
(B) a siloxane copolymer; and
(D) a 1,2-quinonediazide compound,
wherein the acrylic copolymer comprises a structural unit (a-1) represented by the following Formula 1 and a structural unit (a-2) represented by the following Formula 2 at a weight ratio of 1:4 to 4:1. 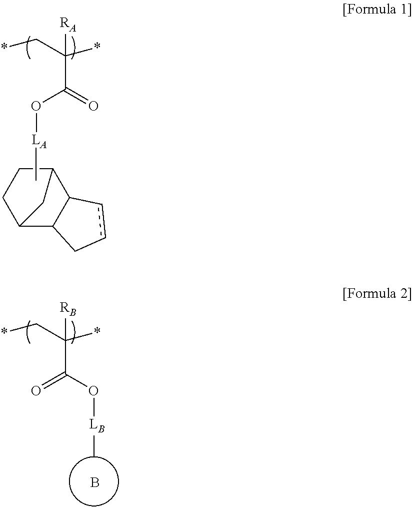
in the above formulae,
R_{A} and R_{B} are each independently hydrogen or a methyl group;
L_{A} and L_{B} are each independently a single bond or a chain having 1 to 6 carbon atoms with or without one or more heteroatoms; [symbol]
is a single bond or a double bond; and
Ring B is a monocyclic ring having 5 to 12 carbon atoms with or without heteroatoms, wherein the ring B has, or does not have, a substituent comprising a hydrocarbon having 1 to 12 carbon atoms, and
the heteroatoms are each selected from the group consisting of N, O, and S.

2. The positive-type photosensitive resin composition of claim 1, wherein the structural unit (a-2) is derived from one or more compounds selected from the group consisting of cyclohexyl acrylate, cyclohexyl methacrylate, cyclohexylmethyl acrylate, cyclohexylmethyl methacrylate, 4-methylcyclohexylmethylacrylate, and 4-methylcyclohexylmethyl methacrylate.

3. The positive-type photosensitive resin composition of claim 1, wherein the acrylic copolymer comprises:
(A1) a first acrylic copolymer comprising the structural unit (a-1) and the structural unit (a-2); and
(A2) a second acrylic copolymer comprising a structural unit (a-3) derived from an ethylenically unsaturated carboxylic acid, an ethylenically unsaturated carboxylic anhydride, or a combination thereof and a structural unit (a-4) derived from an ethylenically unsaturated compound different from the structural units (a-1), (a-2), and (a-3).

4. The positive-type photosensitive resin composition of claim 1, wherein the siloxane copolymer comprises a structural unit derived from two or more silane compounds represented by the following Formula 3:
(R¹)ₙSi(OR²)₄₋ₙ [Formula 3]
in Formula 3,
n is an integer of 0 to 3;
R¹ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl; and
R² is each independently hydrogen, C₁₋₆ alkyl, C₂₋₆ acyl, or C₆₋₁₅ aryl, wherein the heteroalkyl, the heteroalkenyl, and the heteroaryl groups each independently have at least one heteroatom selected from the group consisting of N, O, and S.

5. The positive-type photosensitive resin composition of claim 1, which comprises:
10% by weight to 90% by weight of the acrylic copolymer,
5% by weight to 50% by weight of the siloxane copolyrner, and
1% by weight to 20% by weight of the 1,2-quinonediazide compound, based on the solids content exclusive of solvents.

6. The positive-type photosensitive resin composition of claim 1, which further comprises an epoxy compound.

7. A cured film prepared from the positive-type photosensitive resin composition of claim 1.
